(19) United States
(12) Patent Application Publication
(10) Pub. No.: US 2024/0055337 A1
(43) Pub. Date: Feb. 15, 2024

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Hwan Young CHOI, Suwon-si (KR); Seok Hyun LEE, Suwon-si (KR); Jung Min KO, Suwon-si (KR); Seok Geun AHN, Suwon-si (KR)

(21) Appl. No.: 18/309,113

(22) Filed: Apr. 28, 2023

(30) Foreign Application Priority Data
Aug. 11, 2022 (KR) 10-2022-0100637

(51) Int. Cl. H01L 23/498; H01L 23/31; H01L 23/00; H01L 23/535

(52) U.S. Cl. CPC H01L 23/49816; H01L 23/3128; H01L 24/29; H01L 24/16; H01L 23/535; H01L 2224/73265; H01L 2224/32225; H01L 2924/1431

(57) ABSTRACT

A semiconductor package includes a first semiconductor chip having a first top surface and an opposite first bottom surface, first pads on the first top surface, each having a first width and a first height, second pads on the first top surface further outward from a center of the first semiconductor chip, each having a second width less than the first width and a second height greater than the first height. The semiconductor package further includes a second semiconductor chip having a second bottom surface which faces the first top surface and an opposite second top surface, third pads on the second bottom surface which are connected to the first pads, and fourth pads on the second bottom surface which are connected to the second pads. The second bottom surface is convex.

### CROSS-REFERENCE TO RELATED APPLICATION

This application claims priority under 35 U.S.C. § 119 to Korean Patent Application No. 10-2022-0100637, filed on Aug. 11, 2022, in the Korean Intellectual Property Office, the contents of which are herein incorporated by reference in their entirety.

### BACKGROUND

The present disclosure relates to semiconductor packages and methods of fabricating the same.

### 2. DESCRIPTION OF THE RELATED ART

Due to developments in the electronic industry, the demand for highly functional, high-speed, and compact-size electronic components has increased. Accordingly, a method may be used in which several semiconductor chips are stacked and mounted on a single package wiring structure.

Unfortunately, a warpage phenomenon where a semiconductor package is bent may occur due to the difference between thermal expansion coefficients of the elements of the individual semiconductor package. For example, a “smile” warpage phenomenon where corner areas of a semiconductor package that are relatively weak are bent upwardly due to heat may occur.

### SUMMARY

Aspects of the present disclosure provide semiconductor packages with improved product reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor package comprising a first semiconductor chip having a first top surface and an opposite first bottom surface a plurality of first pads are on the first top surface, each having a first width and a first height, and a plurality of second pads on the first top surface further outward from a center of the first semiconductor chip than the first pads, and each having a second width less than the first width and a second height greater than the first height. The semiconductor package further includes a second semiconductor chip having a second bottom surface which faces the first top surface and an opposite second top surface, a plurality of third pads on the second bottom surface and which are connected to the first pads, and a plurality of fourth pads on the second bottom surface and which are connected to the second pads. The second bottom surface is convex.

According to an aspect of the present disclosure, there is provided a semiconductor package comprising a first semiconductor chip having a first top surface and an opposite first bottom surface, a plurality of first pads on the first top surface, each having a first width and a first height, a plurality of second pads on the first top surface further outward from a center of the first semiconductor chip than the plurality of first pads, and each having a second width less than the first width and a second height greater than the first height. The semiconductor package further includes a second semiconductor chip having a second bottom surface which faces the first top surface, an opposite second top surface, a plurality of third pads on the second bottom surface and connected to the plurality of first pads, and a plurality of fourth pads on the second bottom surface and connected to the plurality of second pads. A fillet layer is between the first and second semiconductor chips and surrounds the plurality of first pads, the plurality of second pads, the plurality of third pads and the plurality of fourth pads. A distance between bottom surfaces of the plurality of first pads and the second bottom surface is less than a distance between bottom surfaces of the plurality of second pads and the second bottom surface.

According to an aspect of the present disclosure, there is provided a semiconductor package comprising a first semiconductor chip having a first top surface and an opposite first bottom surface, a second semiconductor chip having a second top surface and an opposite second bottom surface, a fillet layer in a gap between the first and second semiconductor chips, and a molding member covering the first semiconductor chip, the second semiconductor chip, and the fillet layer. The first semiconductor chip includes a plurality of first pads on the first top surface, each having a first width and a first height, a plurality of second pads on the first top surface, each having a second width less than the first width and a second height greater than the first height, a plurality of first bumps are on the plurality of first pads, and a plurality of second bumps are on the second pads. A plurality of through electrodes extend through a substrate of the first semiconductor chip and are connected to the plurality of first pads and the plurality of second pads. The second semiconductor chip includes a plurality of third pads on the second bottom surface and which are connected to the plurality of first bumps, and a plurality of fourth pads on the second bottom surface and which are connected to the plurality of second bumps. The second bottom surface is convex.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a layout view of a semiconductor package according to some embodiments of the present disclosure.

FIG. 2 is a cross-sectional view of the semiconductor package according to some embodiments of the present disclosure.

FIG. 3 is an enlarged cross-sectional view of part P of FIG. 2.

FIG. 4 is a cross-sectional view of a semiconductor package according to some embodiments of the present disclosure.

FIGS. 5 through 7 are enlarged cross-sectional views of part Q of FIG. 4.

FIG. 8 is a layout view of a semiconductor package according to some embodiments of the present disclosure.

FIG. 9 is a cross-sectional view of the semiconductor package of FIG. 8.

FIG. 10 is an enlarged cross-sectional view of part R of FIG. 9.

FIG. 11 is a cross-sectional view of a semiconductor package according to some embodiments of the present disclosure.

FIGS. 12 and 13 are cross-sectional views of semiconductor packages according to some embodiments of the present disclosure.

FIGS. 14 through 21 are cross-sectional views illustrating a method of fabricating a semiconductor package according to some embodiments of the present disclosure.

### DETAILED DESCRIPTION

Embodiments of the present disclosure will be described with reference to the attached drawings.

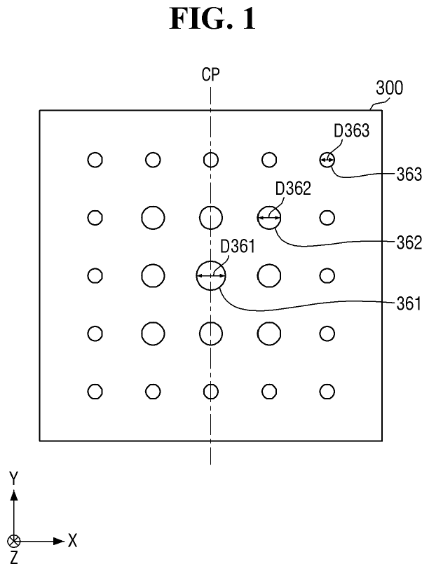

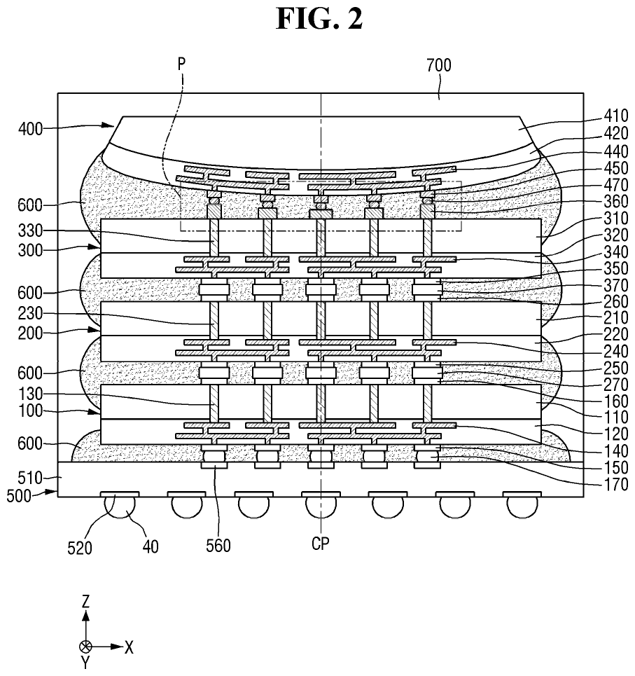

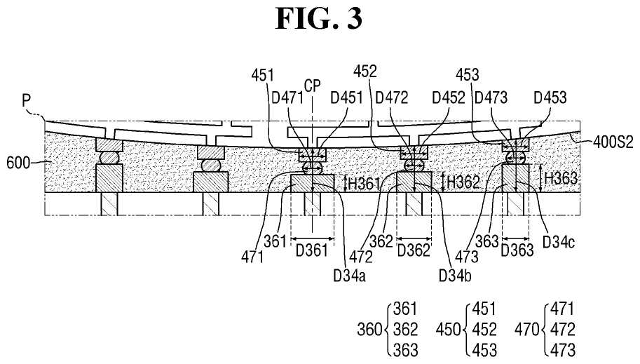

FIG. 1 is a layout view of a semiconductor package according to some embodiments of the present disclosure. FIG. 2 is a cross-sectional view of the semiconductor package according to some embodiments of the present disclosure. FIG. 3 is an enlarged cross-sectional view of part P of FIG. 2.

Referring to FIGS. 1 through 3, the semiconductor package may include first, second, third, and fourth semiconductor chips 100, 200, 300, and 400, a base substrate 500, fillet layers 600, and a molding member 700.

The first, second, third, and fourth semiconductor chips 100, 200, 300, and 400 may be logic chips or memory chips. The first, second, third, and fourth semiconductor chips 100, 200, 300, and 400 may be memory chips of the same type. For example, the first, second, third, and fourth semiconductor chips 100, 200, 300, and 400 may be volatile memory chips such as dynamic random access memories (DRAMs) or static random access memories (SRAMs). In another example, the first, second, third, and fourth semiconductor chips 100, 200, 300, and 400 may be nonvolatile memory chips such as phase-change random-access memories (PRAMs), magnetoresistive random-access memories (MRAMs), ferroelectric random-access memories (FeRAMs), or resistive random-access memories (RRAMs). In another example, the first, second, third, and fourth semiconductor chips 100, 200, 300, and 400 may be high-bandwidth memories (HBMs).

Some of the first, second, third, and fourth semiconductor chips 100, 200, 300, and 400 may be memory chips, and some of the first, second, third, and fourth semiconductor chips 100, 200, 300, and 400 may be logic chips. For example, some of the first, second, third, and fourth semiconductor chips 100, 200, 300, and 400 may be microprocessors, analog devices, digital signal processors (DSPs), or application processors (APs).

The first semiconductor chip 100 may include a first semiconductor substrate 110, a first semiconductor device layer 120, first through electrodes 130, first lower connection pads 150, first upper connection pads 160, and first connection bumps 170.

For example, the first semiconductor substrate 110 may be a bulk silicon or silicon-on-insulator (SOI) substrate. In another example, the first semiconductor substrate 110 may be a silicon (Si) substrate. In another example, the first semiconductor substrate 110 may include silicon germanium, silicon germanium-on-insulator (SGOI), indium antimonide, a lead tellurium compound, indium arsenide, indium phosphide, gallium arsenide, or gallium antimonide, but the present disclosure is not limited thereto.

The first semiconductor substrate 110 may include a conductive region, for example, a well or structure doped with impurities. The first semiconductor substrate 110 may have various device isolation structures such as a shallow trench isolation (STI) structure.

The first semiconductor device layer 120 may be disposed on the bottom surface of the first semiconductor substrate 110. The first semiconductor device layer 120 may include various types of individual devices and interlayer insulating films. Examples of the individual devices include various microelectronic devices, for example, metal-oxide-semiconductor field-effect transistors (MOSFETs) such as complementary metal-oxide-semiconductor (CMOS) transistors, system large-scale integration (LSI), flash memories, DRAMs, SRAMs, electrically erasable programmable read-only memories (EEPROMs), PRAMs, MRAMs, RRAMs, image sensors such as CMOS image sensors, micro-electro-mechanical systems (MEMSs), active elements, passive elements, and the like.

The individual devices of the first semiconductor device layer 120 may be electrically connected to the conductive area formed in the first semiconductor substrate 110. The individual devices of the first semiconductor device layer 120 may be electrically isolated from other individual devices by insulating films. The first semiconductor device layer 120 may include a first wiring structure 140, which electrically connect at least two of the individual devices to the conductive area of the first semiconductor substrate 110.

Although not specifically illustrated, a lower passivation layer, which is for protecting the first wiring structure in the first semiconductor device layer 120 from external shock or moisture, may be formed on the first semiconductor layer 120. The lower passivation layer may expose parts of the top surfaces of the first lower connection pads 150.

The first through electrodes 130 may penetrate the first semiconductor substrate 110. The first through electrodes 130 may extend from the top surface to the bottom surface of the first semiconductor substrate 110. The first through electrodes 130 may be connected to the first wiring structure 140 in the first semiconductor device layer 120.

The first through electrodes 130 may include barrier films, which are formed on the surfaces of pillars, and buried conductive layers, which fill the barrier films. The barrier films may include at least one of titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boride (NiB), but the present disclosure is not limited thereto. The buried conductive layers may include at least one of Cu, an alloy of Cu (e.g., CuSn, CuMg, CuNi, CuZn, CuPd, CuAu, CuRe, or CuW), tungsten (W), an alloy of W, Ni, Ru, and Co, but the present disclosure is not limited thereto.

In some embodiments, an insulating film may be interposed between the first semiconductor substrate 110 and the first through electrodes 130. The insulating film may include an oxide film, a nitride film, a carbide film, a polymer, or a combination thereof, but the present disclosure is not limited thereto.

The first wiring structure 140 may include metal wiring layers and via plugs. For example, the first wiring structure 140 may have a multilayer structure in which two or more metal layers and two or more via plugs are alternately stacked.

The first lower connection pads 150 may be disposed on the first semiconductor device layer 120. The first lower connection pads 150 may be electrically connected to the first wiring structure 140 in the first semiconductor device layer 120. The first lower connection pads 150 may be electrically connected to the first through electrodes 130 through the first wiring structure 140. The first lower connection pads 150 may include at least one of aluminum (Al), Cu, Ni, W, platinum (Pt), and gold (Au).

First upper connection pads 160, which are electrically connected to the first through electrodes 130, may be formed on the top surface of the first semiconductor substrate 110. The first upper connection pads 160 may be formed of the same material as the first lower connection pads 150. Although not specifically illustrated, an upper passivation layer may be formed on the top surface of the first semiconductor substrate 110 to surround parts of the lateral sides of each of the first through electrodes 130.

First connection bumps 170 may be disposed in contact with the first lower connection pads 150. The first connection bumps 170 may electrically connect the first semiconductor chip 100 and the base substrate 500. The first connection bumps 170 may receive control signals, a power signal, and/or a ground signal for driving the first, second, third, and fourth semiconductor chips 100, 200, 300, and 400 from the outside. The first connection bumps 170 may receive data signals to be stored in the first, second, third, and fourth semiconductor chips 100, 200, 300, and 400 from the outside (i.e., from a device or component external to the semiconductor package). The first connection bumps 170 may provide data stored in the first, second, third, and fourth semiconductor chips 100, 200, 300, and 400 to the outside. For example, the first connection bumps 170 may have a pillar structure or a ball structure or consist of a solder layer.

The second semiconductor chip 200 may include a second semiconductor substrate 210 and a second semiconductor device layer 220, which includes a second wiring structure 240, and may also include second through electrodes 230, second lower connection pads 250, second upper connection pads 260, and second connection bumps 270.

The second semiconductor chip 200 may be disposed on the first semiconductor chip 100. The second semiconductor chip 200 may be electrically connected to the first semiconductor chip 100 through the second connection bumps 270, which are disposed between the first and second semiconductor chips 100 and 200.

The third semiconductor chip 300 may be disposed on the second semiconductor chip 200. The third semiconductor chip 300 may include a third semiconductor substrate 310 and a third semiconductor device layer 320, which includes a third wiring structure 340, and may also include third through electrodes 330, third lower connection pads 350, third upper connection pads 360, and third connection bumps 370.

The fourth semiconductor chip 400 may be disposed on the third semiconductor chip 300. The fourth semiconductor chip 400 may include a fourth semiconductor substrate 410 and a fourth semiconductor device layer 420, which includes a fourth wiring structure 440, and may also include fourth lower connection pads 450 and fourth connection bumps 470. The fourth semiconductor chip 400, unlike the first, second, and third semiconductor chips 100, 200, and 300, may not include through electrodes and upper connection pads.

The third upper connection pads 360 may be disposed between the third and fourth semiconductor chips 300 and 400. The third upper connection pads 360 may be disposed on the top surface of the third semiconductor chip 300.

The third upper connection pads 360 may include first, second, and third sub-upper pads 361, 362, and 363. The first, second, and third sub-upper pads 361, 362, and 363 may face a bottom surface 400S2 of the fourth semiconductor chip 400. That is, the third upper connection pads 360 may face the bottom surface 400S2 of the fourth semiconductor chip 400.

The first, second, and third sub-upper pads 361, 362, and 363 may be disposed to be gradually apart from a center CP of the first, second, third, and fourth semiconductor chips 100, 200, 300, and 400. Specifically, the first sub-upper pad 361 may be disposed closest to the center CP of the first, second, third, and fourth semiconductor chips 100, 200, 300, and 400. The second sub-upper pad 362 may be disposed further apart than the first sub-upper pad 361 from the center CP of the first, second, third, and fourth semiconductor chips 100, 200, 300, and 400. That is, the second sub-upper pad 362 may be disposed on the outside of the first sub-upper pad 361. The third sub-upper pad 363 may be disposed further apart than the second sub-upper pad 362 from the center CP of the first, second, third, and fourth semiconductor chips 100, 200, 300, and 400. That is, the third sub-upper pad 363 may be disposed on the outside of the second sub-upper pad 362.

The fourth connection bumps 470 may be disposed between the third and fourth semiconductor chips 300 and 400. The fourth connection bumps 470 may be disposed on the third upper connection pads 360. The fourth connection bumps 470 may be disposed below the fourth lower connection pads 450. The fourth connection bumps 470 may be connected to the fourth lower connection pads 450.

The fourth connection bumps 470 may include first, second, and third sub-bumps 471, 472, and 473. The first sub-bump 471 may be disposed on the first sub-upper pad 361. The first sub-bump 471 may be connected to the first sub-upper pad 361. The second sub-bump 472 may be disposed on the second sub-upper pad 362. The second sub-bump 472 may be connected to the second sub-upper pad 362. The third sub-bump 473 may be disposed on the third sub-upper pad 363. The third sub-bump 473 may be connected to the third sub-upper pad 363.

The fourth lower connection pads 450 may be disposed between the third and fourth semiconductor chips 300 and 400. The fourth lower connection pads 450 may be disposed on the fourth connection bumps 470. The fourth lower connection pads 450 may be disposed on the bottom surface 400S2 of the fourth semiconductor chip 400.

The fourth lower connection pads 450 may include first, second, and third sub-lower pads 451, 452, and 453. The first sub-lower pad 451 may be disposed on the first sub-bump 471. The first sub-lower pad 451 may be connected to the first sub-bump 471. The second sub-lower pad 452 may be disposed on the second sub-bump 472. The second sub-lower pad 452 may be connected to the second sub-bump 472. The third sub-lower pad 453 may be disposed on the third sub-bump 473. The third sub-lower pad 453 may be connected to the third sub-bump 473.

The fourth semiconductor chip 400 may protrude toward the third semiconductor chip 300. Specifically, the bottom surface 400S2 of the fourth semiconductor chip 400 may be convex toward the third semiconductor chip 300.

As the bottom surface 400S2 of the fourth semiconductor chip 400 is convex toward the third semiconductor chip 300, the distance between the top surface of the third semiconductor chip 300 and the bottom surface 400S2 of the fourth semiconductor chip 400 may increase away from the center CP of the first, second, third, and fourth semiconductor chips 100, 200, 300, and 400. As the first, second, and third sub-upper pads 361, 362, and 363 are disposed gradually apart from the center CP of the first, second, third, and fourth semiconductor chips 100, 200, 300, and 400, the distance between the bottom surfaces of the third upper connection pads 360 and the bottom surface 400S2 of the fourth semiconductor chip 400 may also increase away from the center CP of the first, second, third, and fourth semiconductor chips 100, 200, 300, and 400.

For example, the distance between the bottom surface of the first sub-upper pad 361 and the bottom surface 400S2 of the fourth semiconductor chip 400 may be a first distance D34a, the distance between the bottom surface of the second sub-upper pad 362 and the bottom surface 400S2 of the fourth semiconductor chip 400 may be a second distance D34b, and the distance between the bottom surface of the third sub-upper pad 363 and the bottom surface 400S2 of the fourth semiconductor chip 400 may be a third distance D34c. Here, the second distance D34b may be greater than the first distance D34a, and the third distance D34c may be greater than the second distance D34b.

The first sub-upper pad 361 may have a first upper pad width D361 and a first upper pad height H361. The second sub-upper pad 362 may have a second upper pad width D362 and a second upper pad height H362. The third sub-upper pad 363 may have a third upper pad width D363 and a third upper pad height H363. Here, the term “width” may refer to diameter in a plan view.

The first upper pad width D361 may be greater than the second and third upper pad widths D362 and D363. The second upper pad width D362 may be less than the first upper pad width D361 and greater than the third upper pad width D363. The third upper pad width D363 may be less than the first and second upper pad widths D361 and D362.

The first upper pad height H361 may be less than the second and third upper pad heights H362 and H363. The second upper pad height H362 may be greater than the first upper pad height H361 and less than the third upper pad height H363. The third upper pad height H363 may be greater than the first and second upper pad heights H361 and H362.

The width of the third upper connection pads 360 may decrease away from the center CP of the first, second, third, and fourth semiconductor chips 100, 200, 300, and 400. The height of the third upper connection pads 360 may increase away from the center CP of the first, second, third, and fourth semiconductor chips 100, 200, 300, and 400.

As the bottom surface 400S2 of the fourth semiconductor chip 400 is convex toward the third semiconductor chip 300, the adhesion and connection between the third and fourth semiconductor chips 300 and 400 may be unstable. As the height of the third upper connection pads 360 varies depending on the distance between the third and fourth semiconductor chips 300 and 400, the adhesion and connection between the third and fourth semiconductor chips 300 and 400 can be facilitated (i.e., improved).

As the distance between the third and fourth semiconductor chips 300 and 400 increases away from the center CP of the first, second, third, and fourth semiconductor chips 100, 200, 300, and 400, the height of the third upper connection pads 360 also increases away from the center CP of the first, second, third, and fourth semiconductor chips 100, 200, 300, and 400, and as a result, the distance between the third and fourth semiconductor chips 300 and 400 can be compensated for. Accordingly, the fourth semiconductor chip 400 with a curved bottom surface 400S2 can be easily attached onto the third semiconductor chip 300.

For example, the distance between the top surfaces of the third upper connection pads 360 and the bottom surface 400S2 of the fourth semiconductor chip 400 may be uniform regardless of the distance from the center CP of the first, second, third, and fourth semiconductor chips 100, 200, 300, and 400. As the bottom surface 400S2 of the fourth semiconductor chip 400 is convex toward the third semiconductor chip 300, the distance between the third and fourth semiconductor chips 300 and 400 increases away from the center CP of the first, second, third, and fourth semiconductor chips 100, 200, 300, and 400. However, as the height of the third upper connection pads 360 also increases away from the center CP of the first, second, third, and fourth semiconductor chips 100, 200, 300, and 400, the distance between the top surfaces of the third upper connection pads 360 and the bottom surface 400S2 of the fourth semiconductor chip 400 may be uniform. Accordingly, the height of the fourth connection bumps 470, which are disposed on the third upper connection pads 360, and the height of the fourth lower connection pads 450, which are disposed on the fourth connection bumps 470, may be uniform.

The width of the fourth connection bumps 470 may be uniform. For example, the first, second, and third sub-bumps 471, 472, and 473 may have the same width. A width D471 of the first sub-bump 471, which is disposed on the first sub-upper pad 361, a width D472 of the second sub-bump 472, which is disposed on the second sub-upper pad 362, and a width D473 of the third sub-bump 473, which is disposed on the third sub-upper pad 363, may be the same regardless of the distance from the center CP of the first, second, third, and fourth semiconductor chips 100, 200, 300, and 400.

The width of the fourth lower connection pads 450 may be uniform. For example, the first, second, and third sub-lower pads 451, 452, and 453 may have the same width. A width D451 of the first sub-lower pad 451, which is disposed on the first sub-upper pad 361, a width D452 of the second sub-lower pad 452, which is disposed on the second sub-upper pad 362, and a width D453 of the third sub-lower pad 453, which is disposed on the third sub-upper pad 363, may be the same regardless of the distance from the center CP of the first, second, third, and fourth semiconductor chips 100, 200, 300, and 400.

The fillet layers 600 may fill the gaps between the first, second, third, and fourth semiconductor chips 100, 200, 300, and 400.

Specifically, the fillet layers 600 may be disposed between the top surface of the first semiconductor chip 100 and the bottom surface of the second semiconductor chip 200. The fillet layers 600 may attach the second semiconductor chip 200 onto the first semiconductor chip 100. The fillet layers 600 may surround the first upper connection pads 160, the second connection pads 270, and the second lower connection pads 250, which are disposed between the first and second semiconductor chips 100 and 200.

The fillet layers 600 may be disposed between the top surface of the second semiconductor chip 200 and the bottom surface of the third semiconductor chip 300. The fillet layers 600 may surround the second upper connection pads 260, the third connection bumps 370, and the third lower connection pads 350, which are disposed between the second and third semiconductor chips 200 and 300.

The fillet layers 600 may be disposed between the top surface of the third semiconductor chip 300 and the bottom surface of the fourth semiconductor chip 400. The fillet layers 600 may surround the third upper connection pads 360, the fourth connection bumps 470, and the fourth lower connection pads 450, which are disposed between the third and fourth semiconductor chips 300 and 400.

The second, third, and fourth semiconductor chips 200, 300, and 400 may be substantially the same as, or similar to, the first semiconductor chip 100.

The base substrate 500 may be, for example, a printed circuit board (PCB), a ceramic substrate, or an interposer. Alternatively, the base substrate 500 may be a semiconductor chip including semiconductor elements. The base substrate 500 may function as a support substrate for the semiconductor package. For example, the first, second, third, and fourth semiconductor chips 100, 200, 300, and 400 may be stacked on the base substrate 500.

The base substrate 500 may include a substrate body 510, bottom pads 520, and top pads 560. The bottom pads 520 may be disposed on the bottom surface of the substrate body 510. The top pads 560 may be disposed on the top surface of the substrate body 510. External connection terminals 40 may be disposed below the base substrate 500. The external connection terminals 40 may be disposed on the bottom pads 520. For example, the external connection terminals 40 may be solder balls or bumps.

The fillet layers 600 may be formed between the base substrate 500 and the first semiconductor chip 100. The fillet layers 600 may surround the first connection bumps 170 and the first lower connection pads 150, between the base substrate 500 and the first semiconductor chip 100.

The molding member 700 may be formed on the base substrate 500. The molding member 700 may cover the fillet layers 600 and the first, second, third, and fourth semiconductor chips 100, 200, 300, and 400. The molding member 700 may include, for example, a polymer such as a resin. For example, the molding member 700 may include an epoxy molding compound (EMC), but the present disclosure is not limited thereto.

FIG. 2 illustrates that the bottom surface of the fourth semiconductor chip 400 is convex toward the third semiconductor chip 300, but the present disclosure is not limited thereto. Alternatively, the bottom surface of the third semiconductor chip 300 may be convex toward the second semiconductor chip 200, and the bottom surface of the fourth semiconductor chip 400 may not be convex toward the third semiconductor chip 300. Alternatively, the bottom surface of the second semiconductor chip 200 may be convex toward the first semiconductor chip 100, and the bottom surfaces of the third and fourth semiconductor chips 300 and 400 may not be convex.

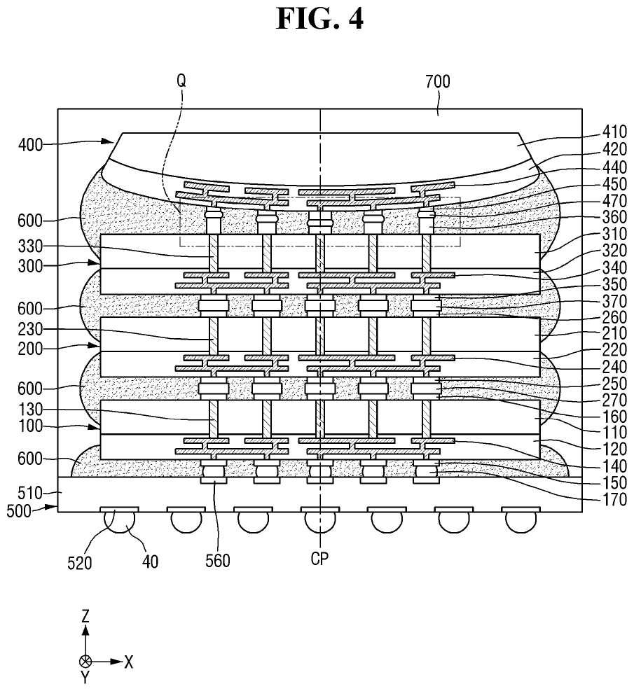

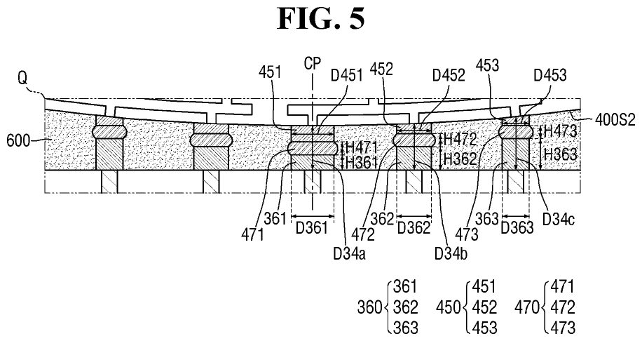

FIG. 4 is a cross-sectional view of a semiconductor package according to some embodiments of the present disclosure. FIGS. 5 through 7 are enlarged cross-sectional views of part Q of FIG. 4. For convenience, the embodiment of FIGS. 4 through 7 will hereinafter be described, focusing mainly on the differences with the embodiment of FIGS. 1 through 3.

Referring to FIGS. 4 and 5, the width of fourth lower connection pads 450 may decrease away from a center CP of first, second, third, and fourth semiconductor chips 100, 200, 300, and 400. A width D451 of a first sub-lower pad 451 may be greater than widths D452 and D453 of second and third sub-lower pads 452 and 453. The width D452 of the second sub-lower pad 452 may be less than the width D451 of the first sub-lower pad 451 and greater than the width D453 of the third sub-lower pad 453. The width D453 of the third sub-lower pad 453 may be less than the widths D451 and D452 of the first and second sub-lower pads 451 and 452.

The height of the fourth lower connection pads 450 may decrease away from the center CP of the first, second, third, and fourth semiconductor chips 100, 200, 300, and 400.

The height of fourth connection bumps 470 may be uniform. For example, first, second, and third sub-bumps 471, 472, and 473 may have the same height. A height H471 of the first sub-bump 471, which is disposed on a first sub-upper pad 361, a height H472 of the second sub-bump 472, which is disposed on a second sub-upper pad 362, and a height H473 of the third sub-bump 471, which is disposed on a third sub-upper pad 363, may be the same regardless of the distance from the center CP of the first, second, third, and fourth semiconductor chips 100, 200, 300, and 400.

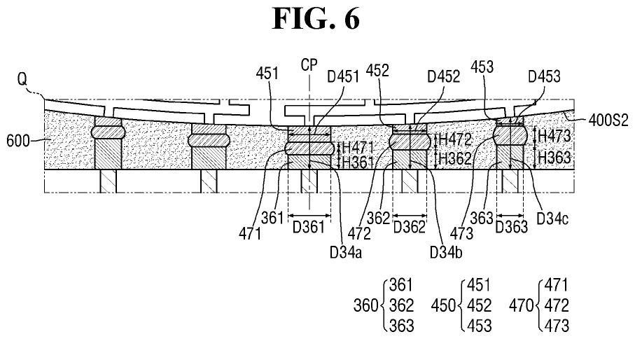

Referring to FIGS. 4 and 6, the height of the fourth connection bumps 470 may increase away from the center CP of the first, second, third, and fourth semiconductor chips 100, 200, 300, and 400. The height H471 of the first sub-bump 471 may be less than the heights H472 and H473 of the second and third sub-bumps 472 and 473. The height H472 of the second sub-bump 472 may be greater than the height H471 of the first sub-bump 471 and less than the height H473 of the third sub-bump 473. The height H473 of the third sub-bump 473 may be greater than the heights H471 and H472 of the first and second sub-bumps 471 and 472.

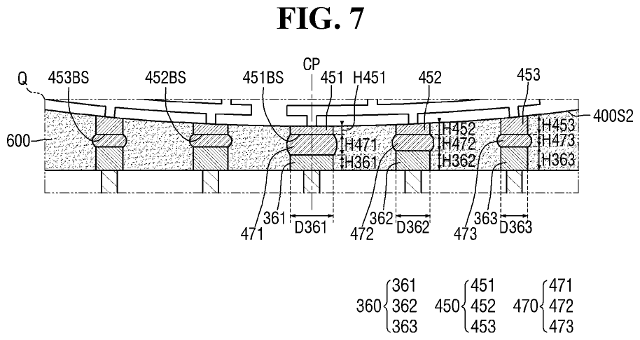

Referring to FIGS. 4 and 7, the height of the fourth connection bumps 470 may decrease away from the center CP of the first, second, third, and fourth semiconductor chips 100, 200, 300, and 400. The height H471 of the first sub-bump 471 may be greater than the heights H472 and H473 of the second and third sub-bumps 472 and 473. The height H472 of the second sub-bump 472 may be less than the height H471 of the first sub-bump 471 and greater than the height H473 of the third sub-bump 473. The height H473 of the third sub-bump 473 may be less than the heights H471 and H472 of the first and second sub-bumps 471 and 472.

The height of the fourth lower connection pads 450 may increase away from the center CP of the first, second, third, and fourth semiconductor chips 100, 200, 300, and 400. A height H451 of the first sub-lower pad 451 may be less than heights H452 and H453 of the second and third sub-lower pads 452 and 453. The height H452 of the second sub-lower pad 452 may be greater than the height H451 of the first sub-lower pad 451 and less than the height H453 of the third sub-lower pad 453. The height H453 of the third sub-lower pad 453 may be greater than the heights H451 and H452 of the first and second sub-lower pads 451 and 452.

For example, bottom surfaces 451BS, 452BS, and 453BS of the first, second, and third sub-lower pads 451, 452, and 453 may be disposed on the same plane (i.e., are co-planar). The bottom surfaces 451BS, 452BS, and 453BS of the first, second, and third sub-lower pads 451, 452, and 453 may be disposed at the same height from the top surface of the third semiconductor chip 300.

As the height of the fourth lower connection pads 450 and the height of third upper connection pads 360 increase away from the center CP of the first, second, third, and fourth semiconductor chips 100, 200, 300, and 400, the distance between the third and fourth semiconductor chips 300 and 400 that increases away from the center CP of the first, second, third, and fourth semiconductor chips 100, 200, 300, and 400 due to the fourth semiconductor chip 400 protruding downwardly can be compensated for.

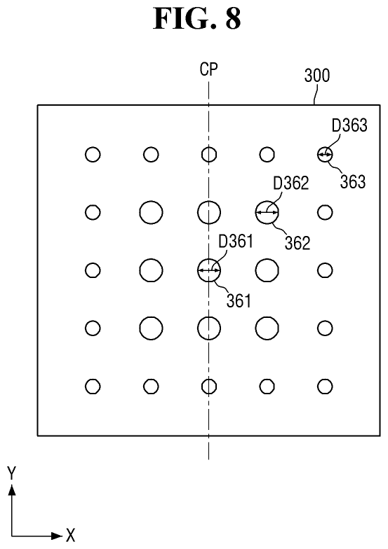

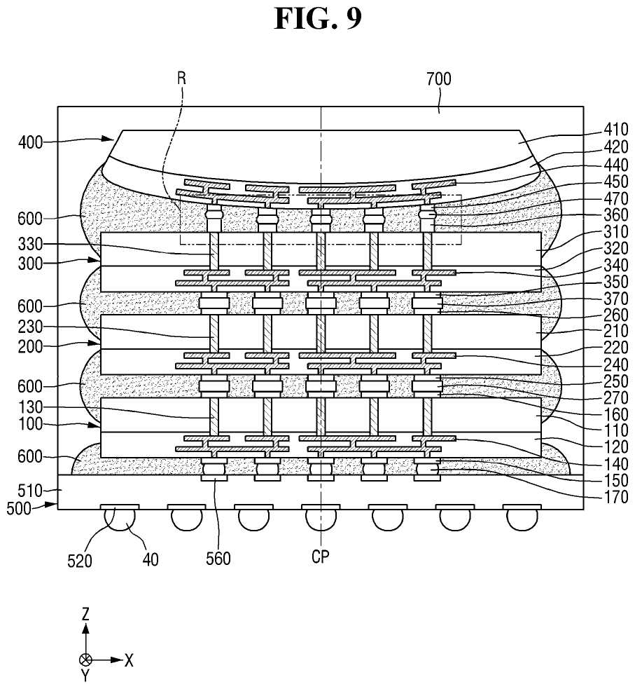

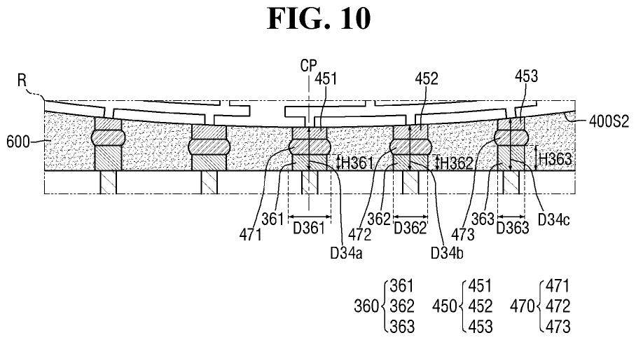

FIG. 8 is a layout view of a semiconductor package according to some embodiments of the present disclosure. FIG. 9 is a cross-sectional view of the semiconductor package of FIG. 8. FIG. 10 is an enlarged cross-sectional view of part R of FIG. 9. For convenience, the embodiment of FIGS. 8 through 10 will hereinafter be described, focusing mainly on the differences with the embodiment of FIGS. 1 through 3.

Referring to FIGS. 8 through 10, first and second sub-upper pads 361 and 362 may have the same width and the same height.

Heights H361 and H362 of the first and second sub-upper pads 361 and 362 may be the same. Widths D361 and D362 of the first and second sub-upper pads 361 and 362 may be the same. A height H363 of a third sub-upper pad 363 may be greater than the height H361 or H362. A width D363 of the third sub-upper pad 363 may be less than the width D361 or D362 of the first or second sub-upper pad 361 or 362.

Even though the second sub-upper pad 362 is disposed further apart than the first sub-upper pad 361 from a center CP of first, second, third, and fourth semiconductor chips 100, 200, 300, and 400, the first and second sub-upper pads 361 and 362 may have the same width and the same height. That is, the first and second sub-upper pads 361 and 362 may be grouped together and may thus be set to the same width and the same height based on the curvature of a bottom surface 400S2 of the fourth semiconductor chip 400.

For example, the first and second sub-upper pads 361 and 362 may have the same width and height in a region where the bottom surface 400S2 of the fourth semiconductor chip 400 is less curved so that the curvature of the bottom surface 400S2 of the fourth semiconductor chip 400 is small, near the center CP of the first, second, third, and fourth semiconductor chips 100, 200, 300, and 400. On the contrary, the height H363 of the third sub-upper pad 363, which is further apart than the first and second sub-upper pads 361 and 362 from the center CP of the first, second, third, and fourth semiconductor chips 100, 200, 300, and 400, may be greater than the height H361 or H362 in a region where the bottom surface 400S2 of the fourth semiconductor chip 400 is curved by a large amount so that the curvature of the bottom surface 400S2 of the fourth semiconductor chip 400 is large, away from the center CP of the first, second, third, and fourth semiconductor chips 100, 200, 300, and 400. Also, the width D363 of the third sub-upper pad 363 may be less than the width D361 or D362 of the first or second sub-upper pad 361 or 362.

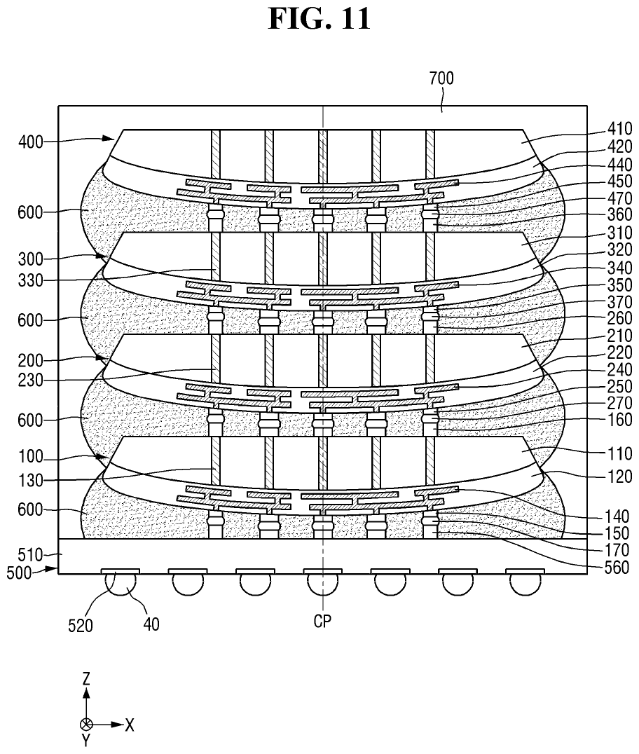

FIG. 11 is a cross-sectional view of a semiconductor package according to some embodiments of the present disclosure. For convenience, the embodiment of FIG. 11 will hereinafter be described, focusing mainly on the differences with the embodiment of FIGS. 1 through 3.

Referring to FIG. 11, the bottom surface of a first semiconductor chip 100 may be convex toward a base substrate 500. That is, the distance between the bottom surface of the first semiconductor chip 100 and the top surface of the base substrate 500 may increase away from a center CP of first, second, third, and fourth semiconductor chips 100, 200, 300, and 400.

The height of top pads 560, which are disposed between the first semiconductor chip 100 and the base substrate 500, may increase away from the center CP of the first, second, third, and fourth semiconductor chips 100, 200, 300, and 400. The width of the top pads 560 may decrease away from the center CP of the first, second, third, and fourth semiconductor chips 100, 200, 300, and 400.

The bottom surface of the second semiconductor chip 200 may be convex toward the first semiconductor chip 100. That is, the distance between the bottom surface of the second semiconductor chip 200 and the top surface of the first semiconductor chip 100 may increase away from the center CP of the first, second, third, and fourth semiconductor chips 100, 200, 300, and 400.

The height of first upper connection pads 160, which are disposed between the first and second semiconductor chips 100 and 200, may increase, but the width of the first upper connection pads 160 may decrease, away from the center CP of the first, second, third, and fourth semiconductor chips 100, 200, 300, and 400.

The bottom surface of the third semiconductor chip 300 may be convex toward the second semiconductor chip 200. That is, the distance between the bottom surface of the third semiconductor chip 300 and the top surface of the second semiconductor chip 200 may increase away from the center CP of the first, second, third, and fourth semiconductor chips 100, 200, 300, and 400.

The height of second upper connection pads 260, which are disposed between the second and third semiconductor chips 200 and 300, may increase, but the width of the second upper connection pads 260 may decrease, away from the center CP of the first, second, third, and fourth semiconductor chips 100, 200, 300, and 400.

The bottom surface of the fourth semiconductor chip 400 may be convex toward the third semiconductor chip 300. That is, the distance between the bottom surface of the fourth semiconductor chip 400 and the top surface of the third semiconductor chip 300 may increase away from the center CP of the first, second, third, and fourth semiconductor chips 100, 200, 300, and 400.

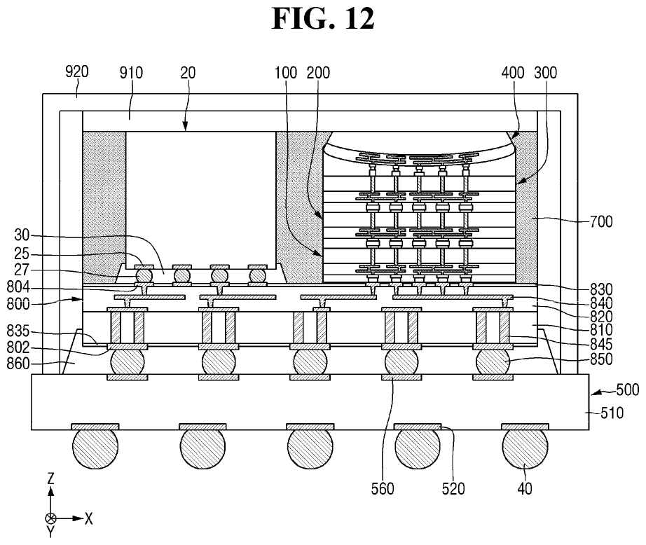

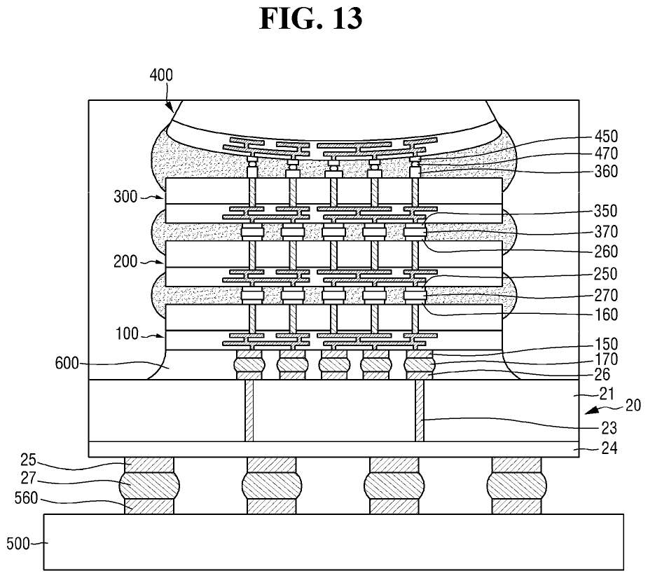

FIGS. 12 and 13 are cross-sectional views of semiconductor packages according to some embodiments of the present disclosure. For convenience, the embodiments of FIGS. 12 and 13 will hereinafter be described, focusing mainly on the differences with the embodiments of FIGS. 1 through 11.

Referring to FIG. 12, the semiconductor package may further include a fifth semiconductor chip 20.

The fifth semiconductor chip 20 may be spaced apart from the first, second, third, and fourth semiconductor chips 100, 200, 300, and 400. For example, the fifth semiconductor chip 20 may be spaced apart from the first, second, third, and fourth semiconductor chips 100, 200, 300, and 400 in a first direction X.

A base substrate 500 may be a substrate for a package. The base substrate 500 may be a PCB. The base substrate 500 may have a bottom surface and a top surface that are opposite to each other. The top surface of the base substrate 500 may face an interposer structure 800.

The base substrate 500 may include a substrate body 510, bottom pads 520, and top pads 560. The bottom pads 520 and the top pads 560 may be used to electrically connect the base substrate 500 and other elements. For example, the bottom pads 520 may be exposed from the bottom surface of the substrate body 510, and the top pads 560 may be exposed from the top surface of the substrate body 510. The bottom pads 520 and the top pads 560 may include a metal material such as, for example, copper (Cu) or aluminum (Al), but the present disclosure is not limited thereto.

Wiring patterns for electrically connecting the bottom pads 520 and the top pads 560 may be formed in the substrate body 510. The substrate body 510 is illustrated as being a single layer, but the present disclosure is not limited thereto. Alternatively, the substrate 510 may be formed as a multilayer, and multilayer wiring patterns may be formed in the substrate body 510.

The base substrate 500 may be mounted on, for example, the main board of an electronic device. For example, external connection terminals 40, which are connected to the bottom pads 520, may be provided. The base substrate 500 may be mounted on the main board of an electronic device through the external connection terminals 40. The base substrate 500 may be a ball grid array (BGA) substrate, but the present disclosure is not limited thereto.

In some embodiments, the base substrate 500 may include a copper clad laminate (CCL). For example, the base substrate 500 may have a structure in which a copper laminate is laminated on one or both sides of thermoset prepreg (e.g., C-Stage prepreg).

The interposer structure 800 may be disposed on the top surface of the base substrate 500. The interposer structure 800 may have a bottom surface and a top surface that are opposite to each other. The top surface of the interposer structure 800 may face the first, second, third, and fourth semiconductor chips 100, 200, 300, and 400 and the fifth semiconductor chip 20. The bottom surface of the interposer structure 800 may face the base substrate 500. The interposer structure 800 can facilitate connecting the base substrate 500, the first, second, third, and fourth semiconductor chips 100, 200, 300, and 400, and the fifth semiconductor chip 20 and can prevent the warpage of the semiconductor package.

The interposer structure 800 may be disposed on the base substrate 500. The interposer structure 800 may include an interposer 810, an interlayer insulating layer 820, a first passivation film 830, a second passivation film 835, wiring patterns 840, interposer vias 845, first interposer pads 802, and second interposer pads 804.

The interposer 810 may be provided on the base substrate 500. The interposer 810 may be, for example, a silicon (Si) interposer, but the present disclosure is not limited thereto. The interlayer insulating layer 820 may be disposed on the interposer 810. The interlayer insulating layer 820 may include an insulating material. For example, the interlayer insulating layer 820 may include at least one of, for example, silicon oxide, silicon nitride, silicon oxynitride, and a low-k material having a lower dielectric constant than silicon oxide, but the present disclosure is not limited thereto.

The first interposer pads 802 and the second interposer pads 804 may be used to electrically connect the interposer 800 to other elements. For example, the first interposer pads 802 may be exposed from the bottom surface of the interposer structure 800, and the second interposer pads 804 may be exposed from the top surface of the interposer structure 800. The first interposer pads 802 and the second interposer pads 804 may include a metal material such as, for example, Cu or Al, but the present disclosure is not limited thereto. Wiring patterns 840 for electrically connecting the first interposer pads 802 and the second interposer pads 804 may be formed in the interposer structure 800.

For example, wiring patterns 840 and the interposer vias 845 may be formed in the interposer structure 800. The wiring patterns 840 may be disposed in the interlayer insulating layer 820. The interposer vias 845 may penetrate the interposer 810. Accordingly, the wiring patterns 840 and the interposer vias 845 may be connected to one another. The wiring patterns 840 may be electrically connected to the second interposer pads 804. The interposer vias 845 may be electrically connected to the first interposer pads 802. Accordingly, the interposer structure 800, the first, second, third, and fourth semiconductor chips 100, 200, 300, and 400, and the fifth semiconductor chip 20 may be electrically connected to one another. The wiring patterns 840 and the interposer vias 845 may include a metal material such as Cu or Al, but the present disclosure is not limited thereto.

The interposer structure 800 may be mounted on the top surface of the base substrate 500. For example, first connection members 850 may be formed between the base substrate 500 and the interposer structure 800. The first connection members 850 may connect the top pads 560 and the first interposer pads 802. Accordingly, the base substrate 500 and the interposer structure 800 may be electrically connected to each other.

The first connection members 850 may be solder bumps including a low-melting-point metal such as, for example, tin (Sn) and an alloy of Sn, but the present disclosure is not limited thereto. The first connection members 850 may have various shapes such as a land shape, a ball shape, a pin shape, or a pillar shape. The first connection members 850 may be formed as single layers or multilayers. The first connection member 850 may be formed as single layers including, for example, Sn-silver (Ag) solder or Cu. Alternatively, the first connection members 850 may be formed as multilayers including, for example, a Cu filler and solder. The number of first connection members 850, the distance between the first connection members 850, and the layout of the first connection members 850 are not particularly limited and may vary depending on the design of the semiconductor package.

In some embodiments, the size of the external connection terminals 40 may be greater than the size of the first connection members 850. For example, the volume of the external connection terminals 40 may be greater than the volume of the first connection members 850.

The first passivation film 830 may be disposed on the interlayer insulating layer 820. The first passivation film 830 may extend along the top surface of the interlayer insulating layer 820. The second interposer pads 804 may penetrate the first passivation film 830 and may thus be connected to the wiring patterns 840. The second passivation film 835 may be disposed on the interposer 810. The second passivation film 835 may extend along the bottom surface of the interposer 810. The first interposer pads 802 may penetrate the second passivation film 835 and may thus be connected to the interposer vias 845.

In some embodiments, the height, in a third direction Z, of the first passivation film 830 may be less than the height, in the third direction Z, of the second interposer pads 804. The second interposer pads 804 may protrude in the third direction Z beyond the first passivation film 830, but the present disclosure is not limited thereto. The height, in the third direction Z, of the second passivation film 835 may be less than the height, in the third direction Z, of the first interposer pads 802. The first interposer pads 802 may protrude in the third direction Z beyond the second passivation film 835, but the present disclosure is not limited thereto.

The first and second passivation films 830 and 835 may include silicon nitride. Alternatively, the first and second passivation films 830 and 835 may include a passivation material, benzocyclobutene (BCB), polybenzoxazole, polyimide, epoxy, silicon oxide, silicon nitride, or a combination thereof.

In some embodiments, first underfill 860 may be formed between the base substrate 500 and the interposer structure 800. The first underfill 860 may fill the space between the base substrate 500 and the interposer structure 800. The first underfill 860 may cover the first connection members 850. The first underfill 860 may prevent breakage of the interposer structure 800 by fixing the interposer structure 800 on the base substrate 500. The first underfill 860 may include, for example, an insulating polymer material such as an EMC, but the present disclosure is not limited thereto.

In some embodiments, the fifth semiconductor chip 20 may be a logic chip. For example, the fifth semiconductor chip 20 may be an application processor (AP) such as a central processing unit (CPU), a graphics processing unit (GPU), a field-programmable gate array (FPGA), a digital signal processor (DSP), a cryptographic processor, a microprocessor, a microcontroller, or an application-specific integrated circuit (ASIC), but the present disclosure is not limited thereto.

In some embodiments, the first, second, third, and fourth semiconductor chips 100, 200, 300, and 400 may be memory chips. For example, the first, second, third, and fourth semiconductor chips 100, 200, 300, and 400 may be volatile memories such as DRAMs or SRAMs or nonvolatile memories such as flash memories, PRAMs, MRAMs, FeRAMs, or RRAMs.

For example, the fifth semiconductor chip 20 may be an ASIC such as a GPU, and the first, second, third, and fourth semiconductor chips 100, 200, 300, and 400 may be stack memories such as high-bandwidth memories (HBMs). Each of the stack memories may have a structure in which multiple ICs are stacked, and the Multiple ICs may be electrically connected to one another via through silicon vias (TSVs).

The fifth semiconductor chip 20 may include fifth lower pads 25. The fifth lower pads 25 may be used to electrically connect the fifth semiconductor chip 20 and other elements. For example, the fifth lower pads 25 may be exposed from the bottom surface of the fifth semiconductor chip 20.

The first, second, third, and fourth semiconductor chips 100, 200, 300, and 400 may be electrically connected to other elements through first lower connection pads 150 (see FIG. 2) and first connection bumps 170 (see FIG. 2).

The fifth semiconductor chip 20 and the first, second, third, and fourth semiconductor chips 100, 200, 300, and 400 may be mounted on the top surface of the interposer structure 800. For example, second connection members 27 may be formed between the interposer structure 800 and the fifth semiconductor chip 20. The second connection members 27 may connect some of the second interposer pads 804 and the fifth lower pads 25. Accordingly, the interposer structure 800 and the fifth semiconductor chip 20 may be electrically connected to each other.

Also, for example, the first lower connection pads 150 and the first connection bumps 170 may be formed between the interposer structure 800 and the first, second, third, and fourth semiconductor chips 100, 200, 300, and 400. The first connection bumps 170 may connect some of the second interposer pads 804 and the first lower connection pads 150. Accordingly, the interposer structure 800 and the first, second, third, and fourth semiconductor chips 100, 200, 300, and 400 may be electrically connected to one another. However, the present disclosure is not limited to this example. Alternatively, the interposer structure 800 and the first, second, third, and fourth semiconductor chips 100, 200, 300, and 400 may be electrically connected to one another through another substrate and a wiring structure between the interposer structure 800 and the first, second, third, and fourth semiconductor chips 100, 200, 300, and 400.

The second connection members 27 may be solder bumps including a low-melting-point metal such as, for example, Sn and an alloy of Sn, but the present disclosure is not limited thereto. The second connection members 27 may have various shapes such as a land shape, a ball shape, a pin shape, or a pillar shape. The second connection members 27 may also include under-bump metallurgy (UBM).

The second connection members 27 may be formed as single layers or multilayers. The second connection members 27 may be formed as single layers including, for example, Sn—Ag solder or Cu. Alternatively, the second connection members 27 may be formed as multilayers including, for example, a Cu filler and solder. The number of second connection members 27, the distance between the second connection members 27, and the layout of the second connection members 27 are not particularly limited and may vary depending on the design of the semiconductor package.

Some of the wiring patterns 840 may electrically connect the fifth semiconductor chip 20 and the first, second, third, and fourth semiconductor chips 100, 200, 300, and 400.

In some embodiments, second underfill 30 may be formed between the interposer structure 800 and the fifth semiconductor chip 20. The second underfill 30 may fill the space between the interposer structure 800 and the fifth semiconductor chip 20. The second underfill 30 may cover the second connection members 27.

The second underfill 30 may prevent breakage of the interposer structure 800 by fixing the interposer structure 800 on the fifth semiconductor chip 20. The second underfill 30 may include, for example, an insulating polymer material such as an EMC, but the present disclosure is not limited thereto.

The molding member 700 may be disposed on the interposer structure 800. The molding member 700 may be provided between the fifth semiconductor chip 20 and the first, second, third, and fourth semiconductor chips 100, 200, 300, and 400. The molding member 700 may separate the fifth semiconductor chip 20 from the first, second, third, and fourth semiconductor chips 100, 200, 300, and 400.

The molding member 700 may include an insulating polymer material such as, for example, an EMC, but the present disclosure is not limited thereto. The molding member 700 may include a different material from the first and second underfills 860 and 30. For example, the first and second underfills 860 and 30 may include an insulating material with better fluidity than the molding member 700. Accordingly, the first and second underfills 860 and 30 can efficiently fill the narrow space between the base substrate 500 and the interposer structure 800 or between the interposer structure 800, the fifth semiconductor chip 20, and the first, second, third, and fourth semiconductor chips 100, 200, 300, and 400.

The semiconductor package may further include an adhesive film 910 and a heat slug 920.

The adhesive film 910 may be provided on the molding member 700. The adhesive film 910 may be provided on the fifth semiconductor chip 20 and the first, second, third, and fourth semiconductor chips 100, 200, 300, and 400. The adhesive film 910 may be in contact with the top surface of the molding member 700. The adhesive film 910 may be in contact with the top surface of the fifth semiconductor chip 20 and the top surfaces of the first, second, third, and fourth semiconductor chips 100, 200, 300, and 400. The adhesive film 910 may bond and fix the molding member 700, the fifth semiconductor chip 20, the first, second, third, and fourth semiconductor chips 100, 200, 300, and 400, and the heat slug 920 together. The adhesive film 910 may include an adhesive material. For example, the adhesive film 910 may include a curable polymer. The adhesive film 910 may include, for example, an epoxy polymer.

The heat slug 920 may be disposed on the base substrate 500. The heat slug 920 may cover the fifth semiconductor chip 20 and the first, second, third, and fourth semiconductor chips 100, 200, 300, and 400. The heat slug 920 may include a metal material, but the present disclosure is not limited thereto.

Referring to FIG. 13, the semiconductor package may further include a fifth semiconductor chip 20, which is vertically stacked on the first, second, third, and fourth semiconductor chips 100, 200, 300, and 400.

The fifth semiconductor chip 20 may be disposed on a base substrate 500. The fifth semiconductor chip 20 may be an IC into which hundreds to millions of semiconductor elements are incorporated. For example, the fifth semiconductor chip 20 may be an AP such as a CPU, a GPU, a FPGA, a DSP, a cryptographic processor, a microprocessor, but the present disclosure is not limited thereto. Alternatively, the fifth semiconductor chip 20 may be a logic chip such as an analog-to-digital converter (ADC) or an ASIC or may be a memory chip such as a volatile memory (e.g., a DRAM) or a nonvolatile memory (e.g., a read-only memory (ROM) or a flash memory). Alternatively, the fifth semiconductor chip 20 may be a combination of an AP, a logic chip, and a memory chip.

The fifth semiconductor chip 20 may be stacked on the top surface of the base substrate 500. For example, top pads 560 may be formed on the top surface of the base substrate 500, and fifth lower pads 25 may be formed on the bottom surface of the fifth semiconductor chip 20. The top pads 560 and the fifth lower pads 25 may be connected by second connection members 27. Accordingly, the base substrate 500 and the fifth semiconductor chip 20 may be electrically connected to each other.

In some embodiments, the first semiconductor chip 100 may be stacked on the fifth semiconductor chip 20. For example, chip pads 26 may be formed on the top surface of the fifth semiconductor chip 20. The chip pads 26 and first lower connection pads 150 may be connected by first connection bumps 170. Accordingly, the fifth semiconductor chip 20 and the first semiconductor chip 100 may be electrically connected to each other.

The fifth semiconductor chip 20 may include a fifth semiconductor substrate 21 and a wiring layer 24. Fifth through electrodes 23 may penetrate the fifth semiconductor substrate 21. In some embodiments, the chip pads 26 may be in contact with the fifth through electrodes 23. For example, the chip pads 26 may penetrate the fifth semiconductor substrate 21 and may thus be in contact with the fifth through electrodes 23, which are exposed from the top surface of the fifth semiconductor chip 20.

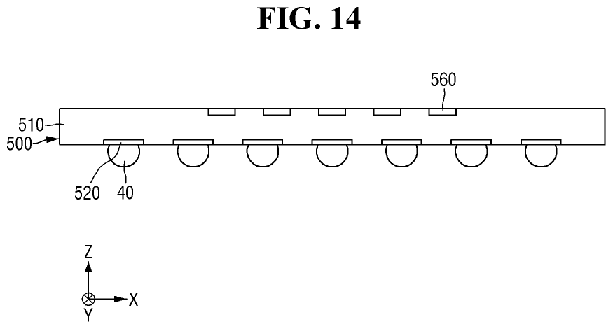

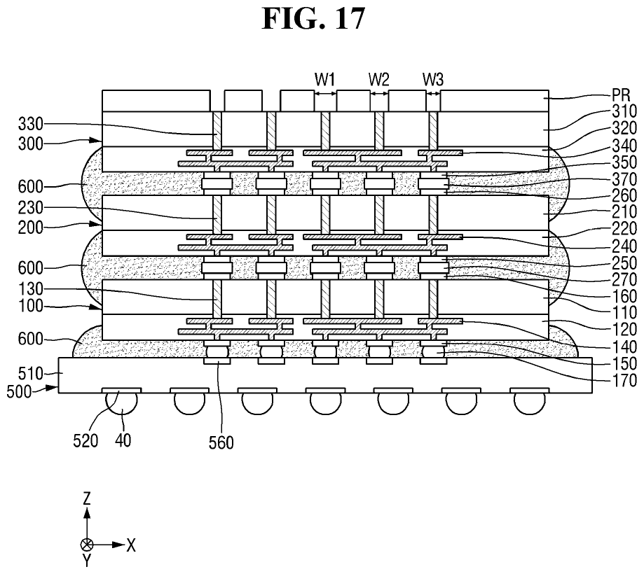

FIGS. 14 through 21 are cross-sectional views illustrating a method of fabricating a semiconductor package according to some embodiments of the present disclosure.

Referring to FIG. 14, a base substrate 500 may be provided.

Specifically, the base substrate 500 may be formed by forming bottom pads 520, top pads 560, and external connection terminals 40 on a substrate body 510.

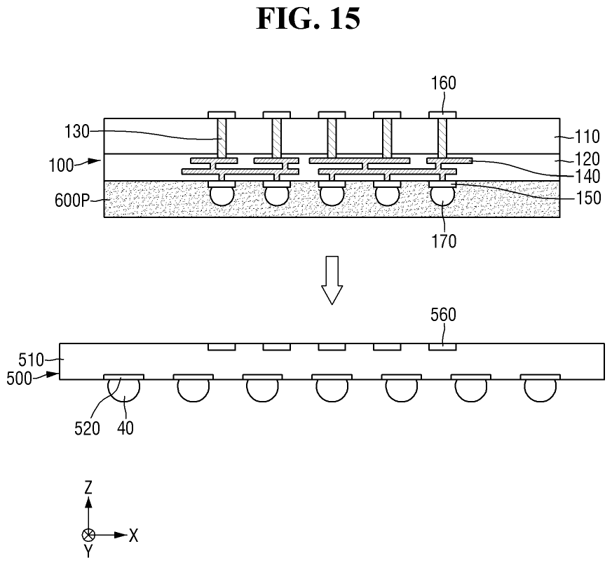

Referring to FIG. 15, a pre-fillet layer 600P is formed below a first semiconductor chip 100.

Specifically, the pre-fillet layer 600P may be formed on the first semiconductor chip to cover first lower connection pads 150 and first connection bumps 170, which are formed below the first semiconductor chip 100. The pre-fillet layer 600P may include a non-conductive film.

Thereafter, the pre-fillet layer 600P and the first semiconductor chip 100 are attached on the base substrate 500.

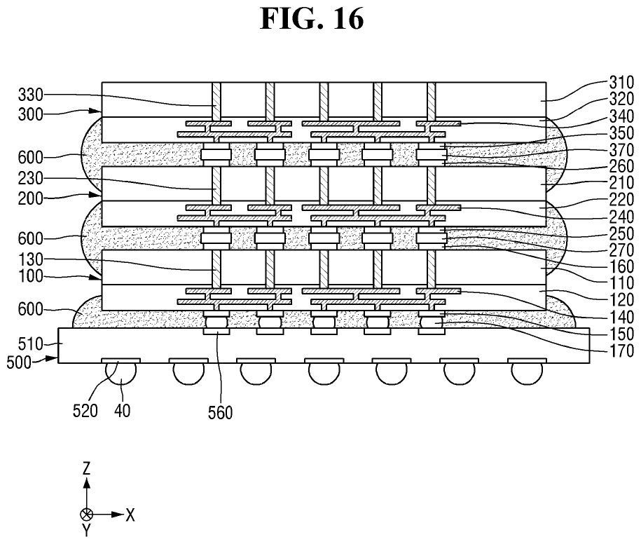

Referring to FIG. 16, a pre-fillet layer 600P may be formed below a second semiconductor chip 200 and may be pressed against the first semiconductor chip 100. A pre-fillet layer 600P may be formed below a third semiconductor chip 300 and may be pressed against the second semiconductor chip 200.

Thereafter, a mask PR may be formed on the third semiconductor chip 300.

The mask PR may include, for example, photoresist.

The mask PR may be formed such that the width of the patterns of the mask PR may decrease away from the center of the third semiconductor chip 300. For example, the mask PR may be formed to have a first width W1 in a first region near the center of the third semiconductor chip 300, a second width W2 in a second region further apart than the first region from the center of the third semiconductor chip 300, and a third width W3 in a third region further apart than the second region from the center of the third semiconductor chip 300.

Here, the first width W1 may be greater than the second and third widths W2 and W3, the second width W2 may be greater than the third width and less than the first width, and the third width W3 may be less than the first and second widths W1 and W2.

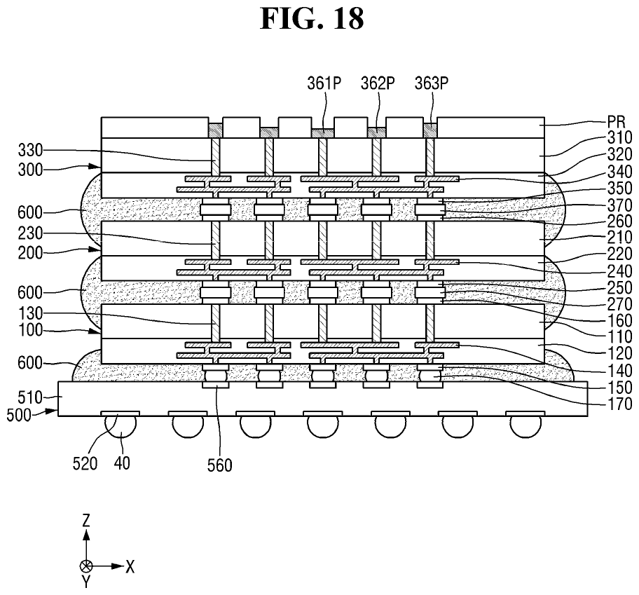

Referring to FIG. 18, first, second, and third pre-sub-upper pads 361P, 362P, and 363P may be formed using the mask PR.

The first, second, and third pre-sub-upper pads 361P, 362P, and 363P may be formed by, for example, electroplating.

As the mask PR has different widths for the first, second, and third pre-sub-upper pads 361P, 362P, and 363P, the first, second, and third pre-sub-upper pads 361P, 362P, and 363P may have different widths and different heights.

Specifically, the first pre-sub-upper pad 361P may be formed in a pattern of the mask PR with the first width W1 to have a larger width than the second and third widths W2 and W3. Accordingly, the first pre-sub-upper pad 361P may be formed to have a larger width than the second and third pre-sub-upper pads 362P and 363P.

The second pre-sub-upper pad 362P may be formed in a pattern of the mask PR with the second width W2 to have a width less than the first width W1, but greater than the third width W3. Accordingly, the second pre-sub-upper pad 362P may be formed to have a height greater than the first pre-sub-upper pad 361P, but less than the third pre-sub-upper pad 363P.

The third pre-sub-upper pad 363P may be formed in a pattern of the mask PR with the third width W3 to have a smaller width than the first and second widths W1 and W2. Accordingly, the third pre-sub-upper pad 363P may be formed to have a greater height than the first and second pre-sub-upper pads 361P and 362P.

That is, the height growth rates of the first, second, and third pre-sub-upper pads 361P, 362P, and 363P can be controlled by controlling the width of the mask patterns of the mask PR.

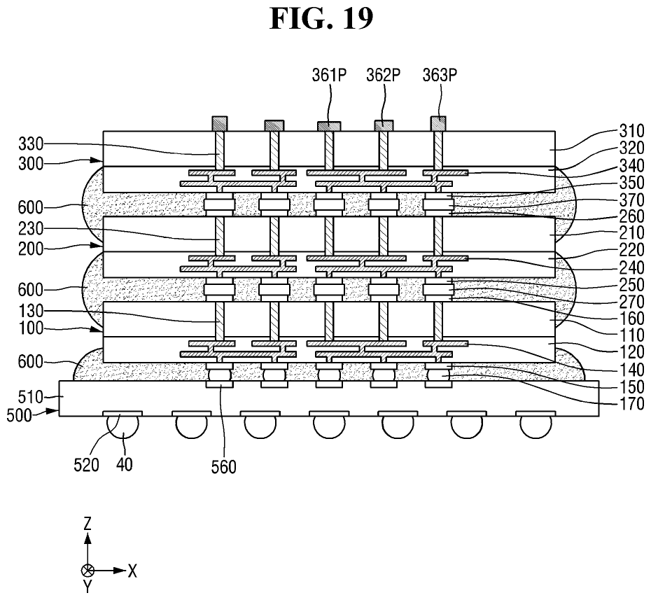

Referring to FIG. 19, the mask PR may be removed.

Accordingly, only the first, second, and third pre-sub-upper pads 361P, 362P, and 363P may remain on the top surface of the third semiconductor chip 300.

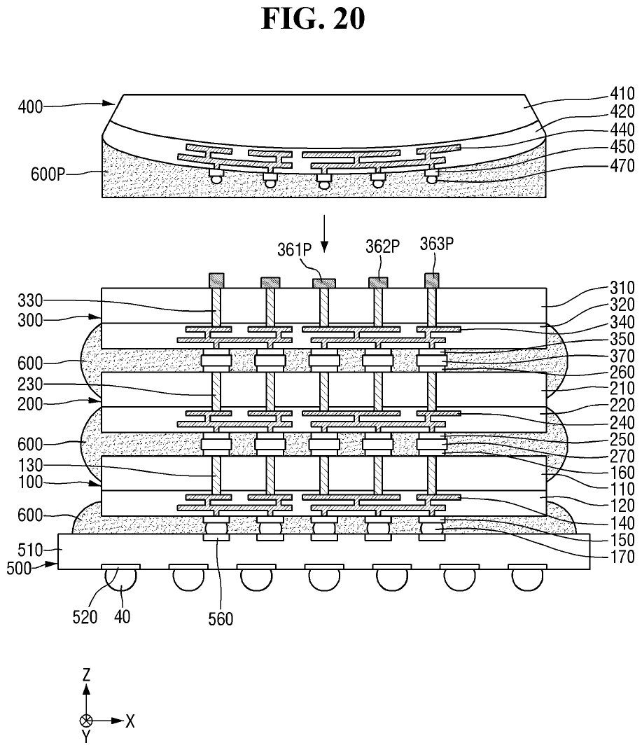

Referring to FIG. 20, a fourth semiconductor chip 400 may be attached on the top surface of the third semiconductor chip 300 and on the first, second, and third pre-sub-upper pads 361P, 362P, and 363P.

Specifically, the bottom surface of the fourth semiconductor chip 400 may be convexly curved toward the third semiconductor chip 300. A pre-fillet layer 600P may be formed on the bottom surface of the fourth semiconductor chip 400. A pre-fillet layer 600P may be formed on the bottom surface of the fourth semiconductor chip 400 to cover fourth lower connection pads 450 and fourth connection bumps 470.

The fourth semiconductor chip 400 with the pre-fillet layer 600P formed thereon may be attached onto the top surface of the third semiconductor chip 300 and on the first, second, and third pre-sub-upper pads 361P, 362P, and 363P.

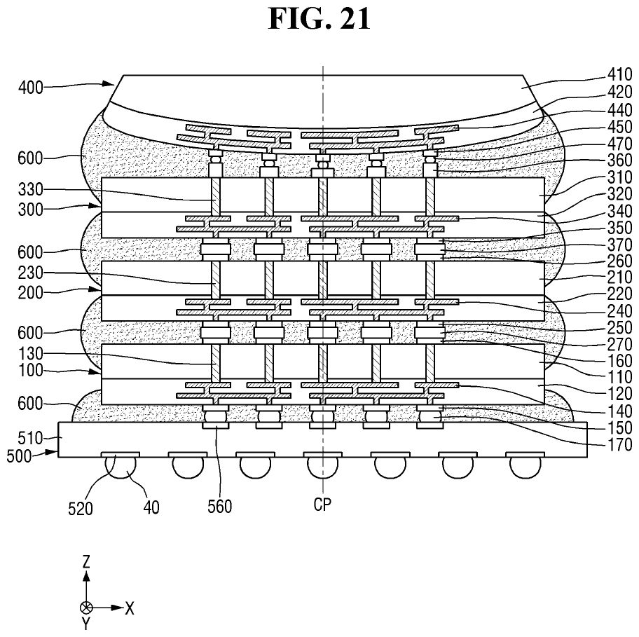

Referring to FIG. 21, third upper connection pads 360 may be formed on the top surface of the third semiconductor chip 300, and a molding member 700 may be formed.

As the first, second, and third pre-sub-upper pads 361P, 362P, and 363P, which have different heights, are disposed on the top surface of the third semiconductor chip 300, the third and fourth semiconductor chips 300 and 400 can be stably attached together even though the bottom surface of the fourth semiconductor chip 400 is convex toward the third semiconductor chip 300.

In concluding the detailed description, those skilled in the art will appreciate that many variations and modifications may be made to the preferred embodiments without substantially departing from the principles of the present invention. Therefore, the disclosed preferred embodiments of the invention are used in a generic and descriptive sense only and not for purposes of limitation.

What is claimed is:

1. A semiconductor package comprising:
a first semiconductor chip comprising a first top surface and an opposite first bottom surface;
a plurality of first pads on the first top surface, each of the plurality of first pads having a first width and a first height;
a plurality of second pads on the first top surface further outward from a center of the first semiconductor chip than the plurality of first pads, each of the plurality of second pads having a second width less than the first width and a second height greater than the first height; and
a second semiconductor chip comprising a second bottom surface which faces the first top surface, and an opposite second top surface, a plurality of third pads on the second bottom surface and connected to the plurality of first pads, and a plurality of fourth pads on the second bottom surface and connected to the plurality of second pads,
wherein the second bottom surface is convex.

2. The semiconductor package of claim 1, wherein
a distance between the plurality of first pads and the plurality of third pads is the same as a distance between the plurality of second pads and the plurality of fourth pads.

3. The semiconductor package of claim 1, wherein a width of each of the plurality of third pads is the same as a width of each of the plurality of fourth pads.

4. The semiconductor package of claim 1, wherein
a width of each of the plurality of third pads is greater than a width of each of the plurality of fourth pads, and
a height of each of the plurality of third pads is less than a height of each of the plurality of fourth pads.

5. The semiconductor package of claim 1, further comprising:
a plurality of first bumps between the plurality of first pads and the plurality of third pads; and
a plurality of second bumps between the second pads and the fourth pads.

6. The semiconductor package of claim 5, wherein a height of each of the plurality of second bumps is greater than a height of each of the plurality of first bumps.

7. The semiconductor package of claim 1, wherein a distance between the second bottom surface and the plurality of first pads is the same as a distance between the second bottom surface and the plurality of second pads.

8. The semiconductor package of claim 1, further comprising:
a fillet layer between the first and second semiconductor chips and surrounding the plurality of first pads, the plurality of second pads, the plurality of third pads, and the plurality of fourth pads.

9. The semiconductor package of claim 1, wherein the first semiconductor chip comprises a substrate and a plurality of through electrodes that extend through the substrate and are connected to the plurality of first pads and the plurality of second pads.

10. The semiconductor package of claim 1, further comprising:
a third semiconductor chip on the second semiconductor chip and comprising a third bottom surface which faces the second top surface, and an opposite third top surface,
wherein the second semiconductor chip further comprises a plurality of fifth pads on the second top surface, wherein each of the plurality of fifth pads has a third width and a third height, and a plurality of sixth pads on the second top surface further outward from a center of the second semiconductor chip than the plurality of fifth pads, and wherein each of the plurality of sixth pads have a fourth width less than the third width and a fourth height greater than the third height, and
wherein the third bottom surface is convex.

11. A semiconductor package comprising:
a first semiconductor chip comprising a first top surface and an opposite first bottom surface;
a plurality of first pads on the first top surface, each of the plurality of first pads having a first width and a first height;
a plurality of second pads on the first top surface further outward from a center of the first semiconductor chip than the plurality of first pads, each of the plurality of second pads having a second width less than the first width and a second height greater than the first height;
a second semiconductor chip comprising a second bottom surface which faces the first top surface, an opposite second top surface, a plurality of third pads on the second bottom surface and connected to the plurality of first pads, and a plurality of fourth pads on the second bottom surface and connected to the plurality of second pads; and
a fillet layer between the first and second semiconductor chips and surrounding the plurality of first pads, the plurality of second pads, the plurality of third pads, and the plurality of fourth pads,
wherein a distance between bottom surfaces of the plurality of first pads and the second bottom surface is less than a distance between bottom surfaces of the plurality of second pads and the second bottom surface.

12. The semiconductor package of claim 11, wherein the second top surface is flat.

13. The semiconductor package of claim 11, wherein a distance between the second bottom surface and the plurality of first pads is the same as a distance between the second bottom surface and the plurality of second pads.

14. The semiconductor package of claim 11, wherein the second bottom surface is convex.

15. The semiconductor package of claim 11, further comprising:
a plurality of first bumps between the plurality of first pads and the plurality of third pads, and wherein the plurality of first bumps are surrounded by the fillet layer; and
a plurality of second bumps between the plurality of second pads and the plurality of fourth pads, and wherein the plurality of second bumps are surrounded by the fillet layer.

16. The semiconductor package of claim 15, wherein a height of each of the plurality of second bumps is greater than a height of each of the plurality of first bumps.

17. The semiconductor package of claim 15, wherein a width of each of the plurality of second bumps is less than a width of each of the plurality of first bumps.

18. The semiconductor package of claim 11, wherein the first semiconductor chip comprises a substrate and a plurality of through electrodes extending through the substrate and connected to the plurality of first pads and the plurality of second pads.

19. The semiconductor package of claim 11, wherein the first and second semiconductor chips comprise high-bandwidth memories (HBMs).

20. A semiconductor package comprising:
a first semiconductor chip comprising a first top surface and an opposite first bottom surface;
a second semiconductor chip comprising a second top surface and an opposite second bottom surface;
a fillet layer in a gap between the first and second semiconductor chips; and
a molding member covering the first semiconductor chip, the second semiconductor chip, and the fillet layer,
wherein the first semiconductor chip comprises a plurality of first pads on the first top surface, each of the plurality of first pads having a first width and a first height, a plurality of second pads on the first top surface, each of the plurality of second pads having a second width less than the first width and a second height greater than the first height, a plurality of first bumps on the plurality of first pads, a plurality of second bumps on the plurality of second pads, and a plurality of through electrodes extending through a substrate of the first semiconductor chip and connected to the plurality of first pads and the plurality of second pads,
wherein the second semiconductor chip comprises a plurality of third pads on the second bottom surface and connected to the plurality of first bumps, and a plurality of fourth pads on the second bottom surface and connected to the plurality of second bumps, and
wherein the second bottom surface is convex.
